(19) United States
(12) Patent Application Publication
(10) Pub. No.: US 2007/0246768 A1
(43) Pub. Date: Oct. 25, 2007

(54) Nonvolatile memory device and method of fabricating the same

(76) Inventors: Kyong-min Kim, Ansan-si (KR); Byoung-dong Kim, Seoul (KR); Sung-ki Seo, Suwon-si (KR)

Correspondence Address: MILLS & ONELLO LLP, ELEVEN BEACON STREET, SUITE 605, BOSTON, MA, 02108, US

(21) Appl. No.: 11/653,592

(22) Filed: Jan. 16, 2007

(30) Foreign Application Priority Data
Jan. 17, 2006 (KR) 10-2006-0004992

(51) Int. Cl. H01L 21/8247; H01L 29/788

(52) U.S. Cl. 257/315; 438/261; 257/E21.209; 257/E21.68; 257/E29.3

(57) ABSTRACT

A nonvolatile memory device and a method of fabricating the same are disclosed. The method includes forming a tunnel oxide film and a conductive film for a floating gate on a semiconductor substrate; nitriding the top surface of the conductive film for a floating gate; oxidizing the nitrided top surface of the conductive film for a floating gate that is nitrided, forming an ONO film comprising a lower oxide film, a nitride film and an upper oxide film sequentially laminated on the surface-modified conductive film for a floating gate to complete formation of the dielectric film; and forming the conductive film for a control gate on the dielectric film.

### CROSS REFERENCE TO RELATED APPLICATION

This application claims priority from Korean Patent Application No. 10-2006-0004992 filed on Jan. 17, 2006 in the Korean Intellectual Property Office, the disclosure of which is incorporated herein by reference in its entirety.

### BACKGROUND OF THE INVENTION

1. Field of the Invention

The present invention relates to a nonvolatile memory device and a method of fabricating the same and, more particularly, to a nonvolatile memory device capable of improving leakage current characteristics and a method of fabricating the same.

2. Description of the Related Art

Among nonvolatile memory devices, for example in an EEPROM (Electrically Erasable Programmable Read Only Memory) that is electrically erasable by the Fowler-Nordheim tunneling phenomenon, electric charges are stored in a floating gate structure by movements of electrons through a thin insulating layer, that is, a tunnel oxide film like SiO₂, and a transistor is turned on/off according to the amount of stored electric charges.

This type of nonvolatile memory device typically has a structure in which a tunnel oxide film, a floating gate, a dielectric film and a control gate are laminated on a suitable substrate. In such a structure, the dielectric film prevents electric charges from moving into the control gate from the floating gate and also prevents electric charge from leaking. On the one hand, the dielectric film in such a structure should reliably serve the function of maintaining capacitance between the floating gate and the control gate; at the same time, the dielectric film should ordinarily preferably be formed with a relatively small thickness.

In such applications, the dielectric film is mainly formed of an ONO (Oxide-Nitride-Oxide) film. Generally, an ONO film is formed by depositing a first MTO (Middle Temperature Oxide) film on a polysilicon film, followed by performing a first N₂ annealing in-situ, then depositing a nitride film, then depositing a second MTO film, and finally performing a second N₂ annealing in-situ.

In such a structure, the MTO film compensates for leakage current of the nitride film and reduces the amount of stress for nitride film. Electric charges are prevented from being lost at the time of programming this type of nonvolatile memory device because the N₂ annealing step is performed after depositing the MTO film.

However, while N₂ annealing is performed after depositing the MTO film in the above-described process, oxides present inside the MTO film can still react with the polysilicon film under the MTO film and thus form an additional oxide film, with the undesirable result that the total thickness of the dielectric film increases. Therefore, the capacitance of this type of nonvolatile memory device decreases, thereby adversely affecting the low power and high-speed operation of the nonvolatile memory device.

These and other limitations and disadvantages of the prior art devices and methods in this field are overcome in whole or at least in part by the devices and methods of this invention.

### SUMMARY OF THE INVENTION

Accordingly, a general object of an exemplary embodiment of the present invention is to provide methods of fabricating nonvolatile memory devices in a way that is capable of improving leakage current characteristics of the resulting nonvolatile memory devices.

Further, another object of the present invention is to provide nonvolatile memory devices fabricated by the methods of this invention.

Objects of the present invention are not limited to those mentioned above, and other objects of the present invention will be apparent to and understood by those skilled in the art through the following description.

In order to achieve the above-described objects, according to an aspect of the present invention, there is provided a method of fabricating a nonvolatile memory device. The exemplary method includes the sequential steps of: forming a tunnel oxide film followed by forming a conductive film as a floating gate on a semiconductor substrate; nitriding the top surface of the conductive film for a floating gate; oxidizing the nitrided top surface of the conductive film for a floating gate; forming an ONO film in which a lower oxide film, a nitride film and an upper oxide film are laminated on the surface-modified conductive film to complete formation of a dielectric film; and forming a conductive film as another step in forming a control gate on the dielectric film.

In order to achieve the above-described objects according to another aspect of the present invention, there is provided a nonvolatile memory device. The nonvolatile memory device sequentially includes: a tunnel oxide film formed on a semiconductor substrate; a floating gate formed on the tunnel oxide film; a dielectric film comprising an anti-oxidation film in which a nitride film and an oxide nitride film are sequentially laminated on the floating gate and an ONO film wherein a lower oxide film, a nitride film and an upper oxide film are sequentially laminated; and a control gate formed on the dielectric film.

Other aspects of the present invention will be included in the detailed description of the invention and the drawings.

### BRIEF DESCRIPTION OF THE DRAWINGS

The above and other features and advantages of the present invention will become more apparent by describing in detail preferred embodiments thereof with reference to the attached drawings, in which:

FIG. 1 is a schematic cross-sectional view of a nonvolatile memory device according to an embodiment of the present invention; and

FIGS. 2 to 6 are views sequentially schematically illustrating a method of fabricating the nonvolatile memory device according to the FIG. 1 embodiment of the present invention.

### DESCRIPTION OF THE PREFERRED EMBODIMENTS

Advantages and features of the present invention and methods of accomplishing the same may be understood more readily by reference to the following detailed description of preferred embodiments and the accompanying drawings. The present invention may, however, be embodied in many different forms and should not be construed as being limited to the embodiments set forth herein. Rather, these embodiments are provided so that this disclosure will be thorough and complete and will fully convey the concept of the invention to those skilled in the art, and the present invention will only be defined by the appended claims. Like reference numerals refer to like elements throughout the specification.

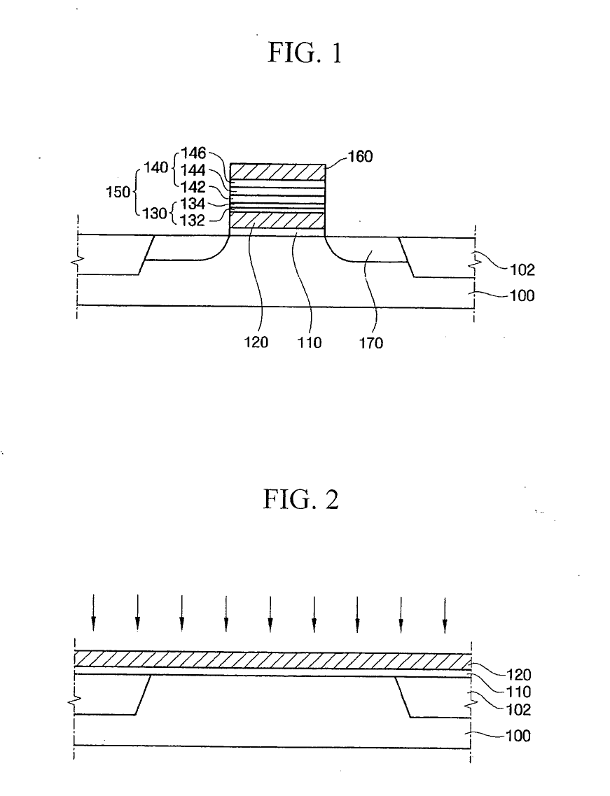

First, the structure of a nonvolatile memory device according to an embodiment of the present invention will be described with reference to FIG. 1. FIG. 1 is a schematic cross-sectional view of the nonvolatile memory device according to the described embodiment of the present invention.

As shown in FIG. 1, the nonvolatile memory device according to the embodiment of the present invention includes a tunnel oxide film 110 on a semiconductor substrate 100, a floating gate 120 on the tunnel oxide film 110, an anti-oxidation film 130 on the floating gate 120, an ONO film 140 on the anti-oxidation film 130, and a control gate 160 on the ONO film 140.

To be more specific, an element isolation film 102 divides a surface of a semiconductor substrate 100 into a field region and an active region, and a gate stack is formed on the active region in which the tunnel oxide film 110, the floating gate 120, a dielectric film 150 (comprising anti-oxidation film 130 and ONO film 140), and the control gate 160 are sequentially laminated. In the nonvolatile memory device with this structure, storage and erasure of data is performed by applying a proper voltage on the control gate 160 and the semiconductor substrate 100 and then inserting or extracting electric charges into or from the floating gate 120.

Here, the tunnel oxide film 110 is formed on the semiconductor substrate 100 so as to have a thickness in a range of about 50 to 100 Å to provide a path for delivering electric charges to the semiconductor substrate 100 and/or the floating gate 120 by means of an F-N tunneling procedure during storing and erasing of data of the nonvolatile memory device.

The floating gate 120 positioned on the tunnel oxide film 110 can be formed of polysilicon, for example, and can accumulate the electric charges delivered by the tunnel oxide film 110.

The dielectric film 150 having a laminated structure of the anti-oxidation film 130 and ONO film 140 is formed on the floating gate 120. Here, the anti-oxidation film 130 which is formed on the top surface of the floating gate 120 comprises a nitride film 132 and an oxide nitride film 134 sequentially laminated. Next, an ONO film 140 comprising a lower oxide film 142, a nitride film 144, and an upper oxide film 146 are sequentially laminated on the oxide nitride film 134.

The dielectric film 150 serves as a barrier between the floating gate 120 and the control gate 160, preserves characteristics of electric charges accumulated in the floating gate 120, and delivers voltage applied on the control gate 160 to the floating gate 120.

In a dielectric film 150 with this structure, the anti-oxidation film 130 formed on the floating gate 120 prevents the thickness of the lower oxide film 142 from increasing due to a possible reaction between the lower oxide film 142 of the ONO film 140 and the floating gate 120. That is, the lower oxide film 142 of the ONO film 140 is positioned on the film 134 which is formed by oxidation, thus preventing the thickness of the oxide film 142 from increasing. Therefore, the dielectric film 150 can be formed with a relatively small overall thickness, thereby increasing capacitance of the nonvolatile memory device and improving leakage current characteristics.

Further, a control gate 160 formed of polysilicon is formed on the dielectric film 150, and the control gate 160 maintains the voltage of the floating gate 120.

A source/drain 170 can then be formed inside the semiconductor substrate 100 at both sides of the gate stack with this structure, as seen in FIG. 1.

Hereinafter, the method of fabricating a nonvolatile memory device according to one embodiment of the present invention will be described with reference to FIGS. 2 to 6. FIGS. 2 to 6 are views sequentially illustrating a method of fabricating a nonvolatile memory device according to an embodiment of the present invention.

First, as shown in FIG. 2, an element isolation process for dividing the substrate surface into an active region and a field region is performed on the semiconductor substrate 100 to form the element isolation film 102. A LOCOS (Local Oxidation of Silicon) process or a STI (Shallow Trench Isolation) process can be used as the element isolation process.

Next, the tunnel oxide film 110 and the conductive film 120 for creating a floating gate are sequentially formed on the semiconductor substrate 100. The tunnel oxide film 110 can be formed of a thermal oxide film by performing a thermal treatment on the semiconductor substrate 100 in an oxygen atmosphere. The conductive film 120 for creating a floating gate is formed on the tunnel oxide film 110 by performing a deposition process, such as CVD (Chemical Vapor Deposition), on polysilicon. Here, the conductive film 120 for a floating gate is formed with a supply of silane-based gas such as SiH₄ at a temperature in a range of about 550° C. to 620° C. and at a pressure in a range of about 20 to 40 Pa. When the conductive film 120 for a floating gate is formed, SiH₄ gas remains at about 0.1 to 1.0 slm and PH₃ gas remains at about 0.01 to 0.1 slm.

Then, before the lower oxide film 142 of the ONO film 140 is formed on the conductive film 120 for a floating gate, the anti-oxidation film (refer to 130 of FIG. 4) is first formed to prevent reaction between silicon substances inside the floating gate 120 and oxides inside the lower oxide film 142.

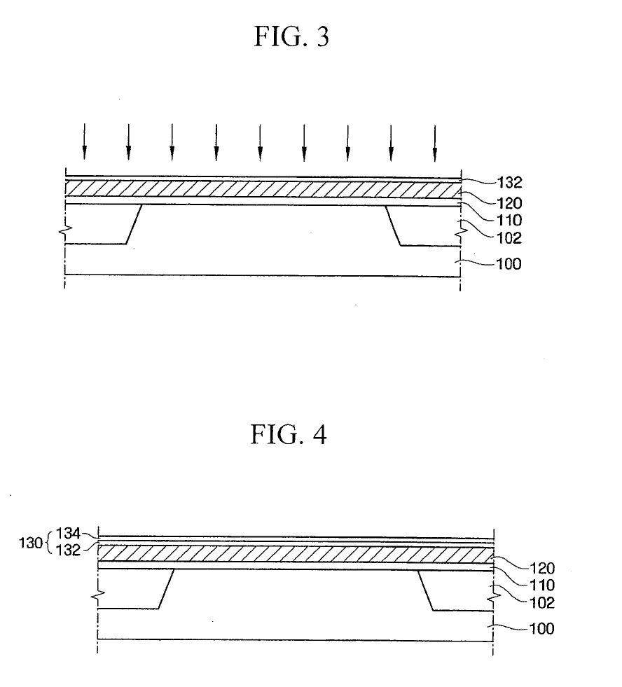

That is, as shown in FIG. 3, a thin nitride film 132 is formed by nitriding the top surface of the conductive film 120 for a floating gate. In the nitriding step, an NH₃ or N₂ plasma process is performed for about 60 to 180 seconds at a temperature in a range of about 300° C. to 600° C. and pressure in a range of about 0.1 to 0.2 torr. Here, the nitriding step can be performed in-situ using a supply of NH₃ or N₂ gas inside a chamber in which the conductive film 120 for a floating gate is formed. In performing this process, NH₃ or N₂ gas remains at about 100 to 2000 sccm, and RF power in a range of about 50 to 500 W is applied.

Next, as shown in FIG. 4, a thin oxide nitride film 134 is formed by oxidizing the surface of the nitride film 132 that is formed by the nitriding process. In this oxidizing step, an N₂O or O₂ plasma process is performed for about 30 to 120 seconds at a temperature in a range of about 300° C. to 600° C. and pressure in a range of about 0.1 to 0.2 torr. This process can be performed in-situ using a supply of N₂O or O₂ gas inside the same chamber in which the nitride film 132 was formed. In performing this process, N₂O or O₂ gas remains at about 100 to 2000 sccm, and RF power in a range of about 50 to 500 W is applied.

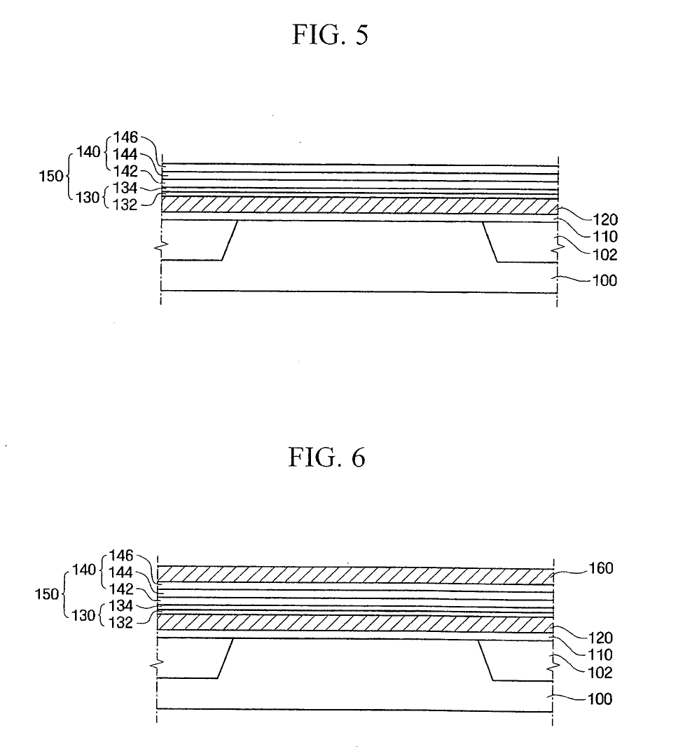

Next, as shown in FIG. 5, the ONO film 140, comprising the lower oxide film 142, the nitride film 144, and the upper oxide film 146 sequentially laminated, is formed on the oxide nitride film 134 of the anti-oxidation film 130 to complete formation of the dielectric film 150. When the ONO film 140 is formed, the lower and upper oxide films 142 and 146 can be formed by depositing oxides. That is, the lower and upper oxide films 142 and 146 can be formed, for example, of an MTO (Middle Temperature Oxide) film, which is known in the art.

To be more specific, the lower and upper oxide films 142 and 146 of the ONO film 140 can be formed of an MTO film by performing deposition using SiH₄ and N₂O gas at a temperature in a range of about 700° C. to 760° C. and pressure in a range of about 80 to 120 Pa. Here, SiH₄ gas remains at about 1 to 10 sccm and N₂O gas at about 1 to 3 slm.

The nitride film 144 formed on the lower oxide film 142 is formed by performing deposition using SiH₂Cl₂ and NH₃ gas at a temperature in a range of about 650° C. to 670° C. and pressure in a range of about 10 to 30 Pa. When the nitride film is formed, SiH₂Cl₂ gas remains at about 0.01 to 0.1 slm and NH₃ gas at about 0.2 to 1.0 slm.

The lower oxide film 142 formed this way is formed on the oxide nitride film 134 that previously was formed by oxidation, which prevents reaction between silicon substances of the conductive film 120 for a floating gate and lower oxide film 142. Therefore, the thickness of the lower oxide film 142 is prevented from increasing, and thus the dielectric film 150 can be reliably formed with a relatively small thickness, such as a thickness in a range of about 50 to 100 Å.

After formation of the dielectric film 150 is completed, a mask is formed on the dielectric film 150. The tunnel oxide film 110, the conductive film 120 for a floating gate and the dielectric film 150 are then sequentially patterned to divide them in one direction. That is, the tunnel oxide film 110, the conductive film 120 for a floating gate and the dielectric film 150 are respectively divided in a direction orthogonal to the cross-sectional surface of the drawings. This patterning process can alternatively be performed before forming the dielectric film 150 so as to exclusively pattern the tunnel oxide film 110 and the conductive film 120 for a floating gate.

Next, as shown in FIG. 6, the conductive film 160 for a control gate is formed by depositing polysilicon on the dielectric film 150. In forming the conductive film 160, the conductive film 160 for a control gate is formed using a supply of silane-based gas such as SiH₄ of about 0.1 to 1.0 slm and PH₃ impurity gas of about 0.01 to 0.1 slm at a temperature in a range of about 550° C. to 620° C. and pressure in a range of about 20 to 40 Pa.

Next, an etching mask (not shown) is formed on the conductive film 160 for a control gate, and then etched until the surface of the semiconductor substrate 100 is exposed to form a gate stack. Next, the source/drain 170 is formed in the semiconductor substrate 100 at both sides of the gate stack to complete the formation of the nonvolatile memory device as shown in FIG. 1.

Although the present invention has been described in connection with the exemplary embodiments of the present invention, it will be apparent to those skilled in the art that various modifications and changes may be made thereto without departing from the scope and spirit of the invention. Therefore, it should be understood that the above embodiments are not limiting, but rather are merely illustrative in all aspects.

As described above, according to a method of fabricating a nonvolatile memory device of the present invention and a nonvolatile memory device fabricated thereby, since the anti-oxidation film is formed by nitriding and oxidizing the upper part of the floating gate, it is possible to prevent reaction between oxides inside the lower oxide film and silicon inside the floating gate formed of polysilicon, thereby preventing the thickness of the lower oxide film from increasing.

Therefore, the dielectric films according to this invention can be reliably formed with a relatively small thickness, which can thereby increase capacitance of the nonvolatile memory device and improve leakage current characteristics of the nonvolatile memory device.

What is claimed is:

1. A method of fabricating a nonvolatile memory device, the method comprising the sequential steps of:
forming a tunnel oxide film and a conductive film for a floating gate on a semiconductor substrate;
nitriding a top surface of the conductive film for a floating gate;
oxidizing the nitrided top surface of the conductive film for a floating gate to form a surface-modified conductive film;
forming an ONO film comprising a lower oxide film, a nitride film and an upper oxide film sequentially laminated on the surface-modified conductive film for a floating gate to complete the formation of a dielectric film; and
forming a conductive film for a control gate on the dielectric film.

2. The method of claim 1, wherein in the nitriding and oxidizing steps, an anti-oxidation film is formed in which a nitride film and an oxide nitride film are sequentially laminated on the surface of the conductive film under the ONO film.

3. The method of claim 1, wherein in the nitriding step, an NH₃ or N₂ plasma process is performed on the surface of the conductive film for a floating gate.

4. The method of claim 3, wherein the nitriding step is performed for about 60 to 180 seconds at a temperature in a range of about 300° C. to 600° C. and at a pressure in a range of about 0.1 to 3.0 torr.

5. The method of claim 3, wherein in the nitriding step, NH₃ or N₂ gas remains at about 100 to 2000 sccm.

6. The method of claim 3, wherein the nitriding step is performed at RF power in a range of about 50 to 500 W.

7. The method of claim 1, wherein in the oxidizing step, an N₂O or N₂ plasma process is performed on the nitrided surface of the conductive film for a floating gate.

8. The method of claim 7, wherein the oxidizing step is performed for about 30 to 120 seconds at a temperature in a range of about 300° C. to 600° C. and at a pressure in a range of about 0.1 to 3.0 torr.

9. The method of claim 7, wherein in the oxidizing step, N₂O or O₂ gas remains at about 100 to 2000 sccm.

10. The method of claim 7, wherein the oxidizing step is performed at RF power in a range of about 50 to 500 W.

11. The method of claim 1, wherein the nitriding and oxidizing steps are performed in-situ in a chamber containing the substrate.

12. The method of claim 1, wherein the conductive film for a floating gate and the conductive film for a control gate are formed by depositing polysilicon.

13. The method of claim 1, wherein the lower oxide film and the upper oxide film of the dielectric film are formed of a middle temperature oxide (MTO).

14. The method of claim 13, wherein the floating gate and the control gate are formed of polysilicon.

15. A nonvolatile memory device comprising:
a tunnel oxide film formed on a semiconductor substrate;
a floating gate formed on the tunnel oxide film;
a dielectric film comprising an anti-oxidation film and an ONO film sequentially formed on the floating gate, wherein the anti-oxidation film comprises a nitride film and an oxide nitride film sequentially laminated on the floating gate, the and ONO film comprises a lower oxide film, a nitride film and an upper oxide film sequentially laminated on the anti-oxidation film; and
a control gate formed on the dielectric film.

16. The nonvolatile memory device of claim 15, wherein the lower oxide film and the upper oxide film of the dielectric film are formed of a middle temperature oxide (MTO).

17. The nonvolatile memory device of claim 15, wherein the floating gate and the control gate are formed of polysilicon.

18. The nonvolatile memory device of claim 15, wherein a memory device gate structure is formed on an active region of the substrate.

19. The nonvolatile memory device of claim 15, wherein a source/drain region is formed in the semiconductor substrate at both sides of the memory device structure.
